(19) United States
(12) Patent Application Publication
(10) Pub. No.: US 2012/0008336 A1
(43) Pub. Date: Jan. 12, 2012

(54) Aircraft Lighting System

(75) Inventors: Otward M. Mueller, Ballston Lake, NY (US); Eduard K. Mueller, Ballston Lake, NY (US)

(73) Assignees: Otward Mueller; MTECH Laboratories, LLC; Eduard Mueller

(21) Appl. No.: 12/831,210

(22) Filed: Jul. 6, 2010

(51) Int. Cl. B64D 47/02; H01L 33/02; F21L 4/02

(52) U.S. Cl. 362/555; 362/184; 362/470

(57) ABSTRACT

Described is a novel aircraft lighting system with the potential for achieving increased efficiency, improved thermal management, higher reliability, and longer lifetimes. The proposed approach involves combining solar cells and light-emitting diodes (LEDs), and utilizing the cold temperatures of about −50 degrees centigrade encountered in high-altitude (12,000 m) flight to improve thermal management and efficiency in both components.

### U.S. PATENT DOCUMENTS REFERENCED

D. J. Bennett, D. A. Eijadi: U.S. Pat. No. 4,329,021, May 11, 1982: “Passive Solar Lighting System”.

### BACKGROUND OF THE INVENTION

LEDs: MTECH staff members have measured the light output of various LEDs as a function of current and as a function of temperature, down to 77 K (−196 C). As an example, at a diode current of 1 mA, the light output of a yellow LED at 77 K is about 2 orders of magnitude larger than at 300 K. Therefore, the quantum efficiency of LEDs can be improved significantly by cooling the devices to low temperatures.

Cooling to low temperatures significantly increases the thermal conductivity of the semiconductor material and of the substrates for the semiconductor chips such as BeO, etc. For example, in silicon the increase in thermal conductivity is about a factor of 10 between 400 K and 77 K. Therefore, low-temperature operation improves the thermal management of LEDs at high currents. The same is true for photovoltaic solar cells.

At higher temperatures, the reliability and lifetime of semiconductor devices follow an Arrhenius plot. Extending this data in the other direction, toward lower temperatures, shows dramatic improvements in lifetime and reliability at low temperatures. For example, according to high-temperature data, the lifetimes of semiconductor devices should be longer than the age of the known universe at temperatures below 77 K. While this can obviously not be tested, and while there are no doubt other effects that dominate at low temperatures (especially thermal cycling stresses), the lifetimes should nonetheless be spectacular compared to those at room temperature and above.

The conversion efficiencies of photovoltaic (PV) solar cells also increases with decreasing temperature [14]. In addition, the low-voltage power requirements of light emitting diodes are an ideal match to solar cells generating low voltages.

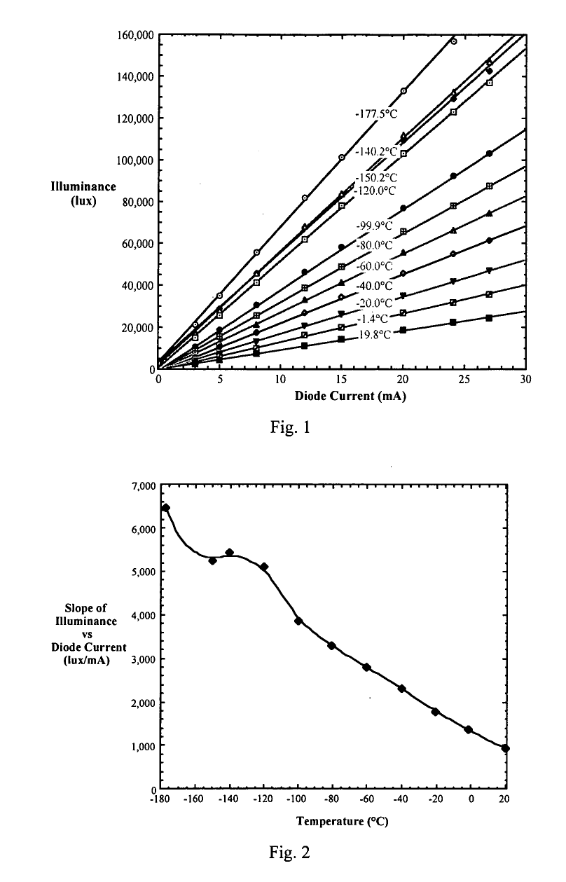

The inventors have measured the temperature-dependent behavior of LEDs and diode lasers to temperatures as low as that of liquid nitrogen (77 K), and have published some of this data in the past [1-5]. Many of the results are promising. For example, FIG. 1 shows that the light output of yellow LEDs for a given current increases significantly as the temperature is decreased [2, 4]. FIG. 2 shows the increase in the slopes of the curves of FIG. 1, which is a direct measure of improved conversion efficiency.

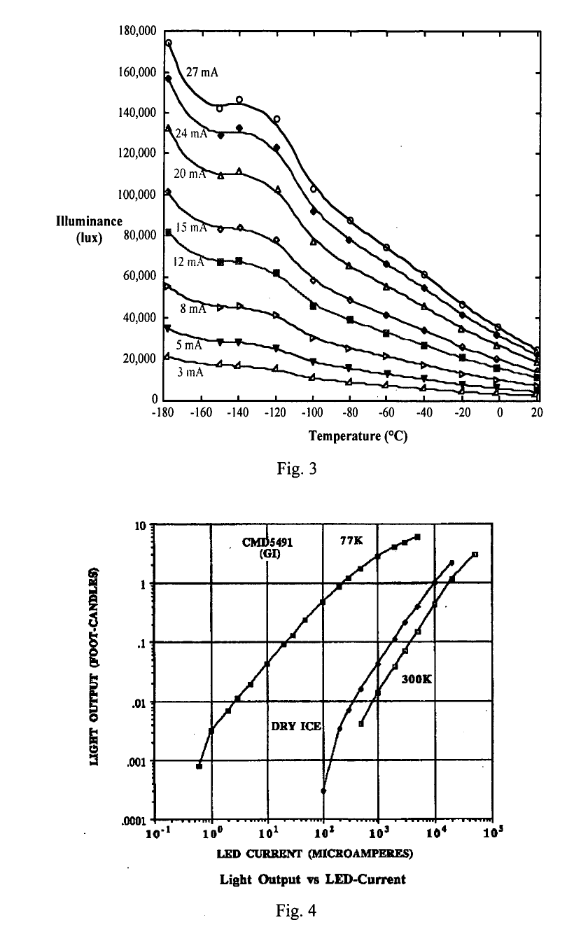

FIG. 3 shows the increase in light output of a yellow LED with decreasing temperature, at various input currents. The efficiency peaks at around minus 135 degrees C. FIG. 4 shows similar measurements for another LED. Even at −50 C (the temperature of the atmosphere at an altitude of 10,000 meters), the efficiency is twice as high as it is at room temperature in some LEDs. Of course, the LED lighting system can also be used without cooling at the normal cabin temperature as is already done in the Boeing 787 Dreamliner.

In most applications, energy must be actively expended to achieve cooling. However, in this system, the cooling is “free.” Solid-state lighting has another advantage: It is the most lightweight of all lighting systems, smaller and lighter than incandescent, fluorescent, and other kinds of lamps. Every kilogram of weight reduction translates into significant fuel savings in airliners flying millions of kilometers in a lifetime. In addition, LEDs have longer lifetimes than all other lighting technologies, thereby reducing maintenance.

In the case that liquid nitrogen (LN₂) is already used somewhere in the airplane, for example for refrigeration of food, one can, of course, also use LN₂ for cooling the LEDs. This will drastically increase the light efficiency of many types of LEDs.

This concept may save fuel in aircraft crossing the globe over their lifetimes. Any improvements in efficiency or reductions in cargo weight help to decrease the carbon footprint of aircraft. Similarly, any decrease in carbon emissions, such as those obtained by reduced fuel usage, will help reduce greenhouse gas emission, becoming part of a global, unified effort to slow the effects of unnaturally induced climate change. As a general rule, it is assumed that every kilogram of weight added to an aircraft must be multiplied by a factor of 2.5 to assess its effect on the airplane's total weight (because of the need for additional fuel). Likewise, any inefficiency introduced into an aircraft must be multiplied by a factor of 1.2 to assess its effect on the total efficiency of the aircraft.

The performance of organic LEDs should also improve as a function of temperature, and these are an option as soon as available.

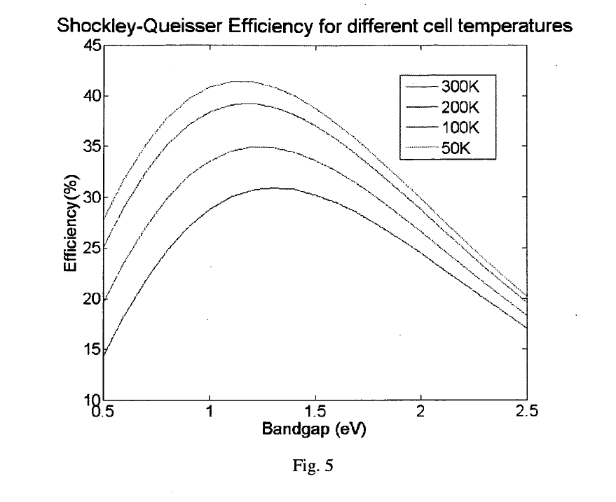

Photovoltaic Solar Cells: MTECH has also carried out a some tests on photovoltaic devices. Similar improvements in efficiency and power output were observed in these devices. The physics involving the maximum possible efficiency of photovoltaic solar cells is described by the Shockley-Queissner Limit curves shown in FIG. 5 [15-17]. FIG. 5 demonstrates the general trend for increasing efficiencies with decreasing temperatures as a function of the bandgap of the various semiconductors used.

Cooling System: Since a human being of average size, at rest in a cabin seat, produces up to 100 watts of power, an air conditioning system is necessary to remove the heat generated, for example about 30 kW per 300 passengers. In the proposed system, this means the cooling of the LEDs can be combined and coordinated with the air conditioning system of the airplane.

Liquid nitrogen could be generated by a cryo-cooler operating at the outside temperature of —50 C (225 Kelvin) with an ideal Carnot efficiency of (225K-77K)/77K=1.92 watts of input power to remove each watt at 77K, instead of (300K-77K)/77K=2.89 W/W. (Of course, the real input power is much higher, but the ratio should hold). The solar panels on the large area wings could produce enough energy to operate the air separation plant.

### DESCRIPTION OF THE INVENTION

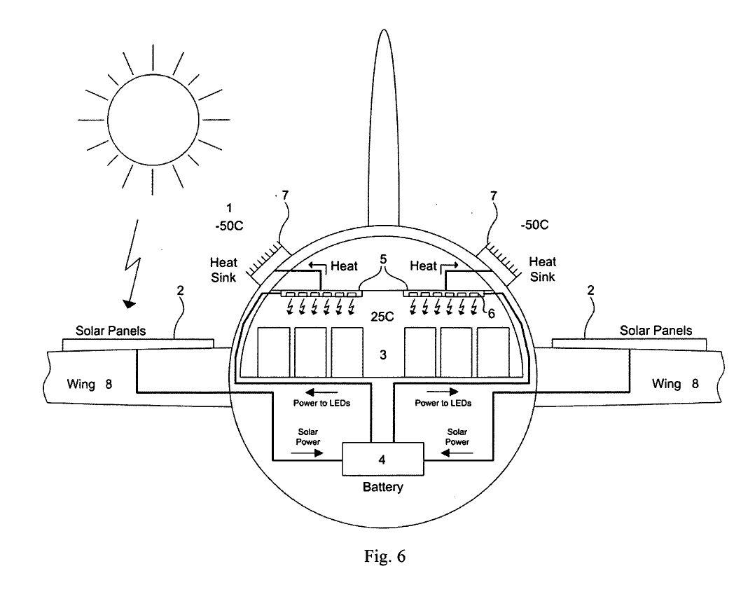

Combining these features, MTECH proposes the following novel concept shown schematically in FIG. 6:
Photovoltaic devices 2 (solar cells) are mounted on the wings and/or the fuselage of airplanes, especially transcontinental airliners flying at altitudes of 10,000 to 12,000 meters above sea level, at which the outside temperature is approximately −50 degrees Celsius (225 Kelvin) in winter and summer, day and night. Since these planes fly above the clouds, they are perfect candidates for the use of photovoltaic cells. The cold atmosphere enhances the conversion efficiencies of these devices (see FIG. 5: Shockley-Queissner Curves).
The solar cells 2 charge the batteries 4 inside the cabin 3 which feed the LEDs 6 mounted on a fixture 5. The LEDs operate with increased efficiency at the cool temperature of the cold fixture 5.
Fixture 5 is thermally coupled to the outside temperature of −50 degree Celsius via thermal couplers, “heat” or cool pipes, 7, and is approximately at the same temperature (−50 C) as the outside atmosphere. Fixture 5 is thermally isolated against the cabin's ambient temperature of about 25 C (˜300 K).
Standard power sources such as the battery 4 can be used during nighttime to power the LEDs.
Light pipes and fiber optic cables can also be used to connect LEDs to the cool hull of the airplane.
If liquid nitrogen is used on the airplane for other purposes such as cooling food in the kitchen, then LN₂ can also be used to cool the LED lighting system.
The fixture 5 thermally connected to the cold (−50 C) outside atmosphere can also be positioned in parallel with the airplane body.
Another possibility would be to generate LN₂ (liquid nitrogen) with a cryo-cooler using the airplane outside atmosphere at −50 C (225 K) as the hot temperature, yielding a much higher (ideal) Carnot efficiency of 1.92 W/W instead of 2.89 W/W.

### PRIOR ART

To the inventors' knowledge, the use of cold external temperatures to increase the efficiency of light emitting diodes, and the combination of enhanced solar cell performance resulting from the same low temperatures has not been described or proposed, and has certainly not been implemented.

### REFERENCES

[1] O. M. Mueller, E. K. Mueller: “The Cryo-LED: Key to Cold-Light?” Proceedings, 4th European Workshop on Low Temperature Electronics—WOLTE 4, WPP-171, ESTEC, The Netherlands, June 2000, pp. 123-129.
[2] E. K. Mueller, et al., “Comparison of Improved Operating Parameters of Five Different Wavelength LED's for Significantly Brighter Illumination”, Photonics West, (SPIE) Opto-Electronics 2001 (OE10)
[3] S. Lee, E. K. Mueller, et al., “Improved Semiconductor Diode Lasers for Light Activation of Pharmaceutical Agents”, Photonics West, (SPIE) BiOS 2001 (BO06)
[4] S. Lee, E. K. Mueller, et al. “Optical Properties and Electronic Requirements for Low Temperature Operation of Yellow Semiconductor LED's”, Photonics West, (SPIE) Opto-Electronics 2001 (OE03)
[5] S. Lee, E. K. Mueller, et al., “Improved Low-Power Semiconductor Diode Lasers for Photodynamic Therapy in Veterinary Medicine”, Photonics West, BiOS 2001 (BO07)
[6] O. M. Mueller, E. K. Mueller, “Efficient Two-Level Cryogenic Power Distribution System”, Cryogenic Engineering Conference/International Cryogenic Materials Conference, Madison, Wis., July 2001
[7] O. M. Mueller, E. K. Mueller, “Analysis of the HTS-Cable/Cryo-Silicon Transformer System”, Applied Superconductivity Conference, Virginia Beach, Va., September 2000
[8] O. M. Mueller, E. K. Mueller, “A Cryogenic Power/Energy Distribution System”, Cryogenic Engineering Conference/International Cryogenic Materials Conference, Montreal, Quebec, Canada, June 1999, Paper CPC-1
[9] O. M. Mueller, E. K. Mueller, “Cryogenic Power Inverters for MRI”, Cryogenic Engineering Conference/International Cryogenic Materials Conference, Montreal, Quebec, Canada, June 1999, Paper CPC-1
[10] E. K. Mueller, O. M. Mueller, “High-Speed Cryo-CMOS Driver Circuits for Power Inverters”, Cryogenic Engineering Conference/International Cryogenic Materials Conference, Montreal, Quebec, Canada, June 1999, Paper CPC-2
[11] R. R. Ward, W. J. Dawson, L. Zhu, R. K. Kirschman, O. Mueller, M. J. Hennessy, E. Mueller, R. L. Patterson, J. E. Dickman and A. Hammoud, “Power diodes for Cryogenic Operation”, PESC-03, Acapulco, Mexico, 2003
[12] R. R. Ward, W. J. Dawson, L. Zhu, R. K. Kirschman, O. Mueller, M. J. Hennessy, E. K. Mueller, R. L. Patterson, J. E. Dickman and A. Hammoud, “Ge Semiconductor Devices for Cryogenic Power Electronics—IV”, Electrochemical Society, 7th International Symposium on Low Temperature Electronics, Orlando, Fla., October 2003
[13] O. Mueller, M. J. Hennessy, and E. K. Mueller, “Performance of High-Voltage IGBTs at Cryogenic Temperatures”, Electrochemical Society, 7th International Symposium on Low Temperature Electronics, Orlando, Fla., October 2003
[14] S. M. Sze: “Physics of Semiconductor Devices”, J. Wiley, 1969, “Solar Cell”, page 644, FIG. 13: “Conversion efficiency as a function of energy gap for ideal current-voltage.”
[15]: Mathew Guenette: “The efficiency of photovoltaic solar cells at low temperatures.” Thesis, August 4^{th}, 2006, pp. 11-20, FIG. 3.2 (Internet).
[16]: William Shockley, Hans Queisser, “Detailed Balance Limit of Efficiency of p-n Junction Solar Cells”, Journal of Applied Physics. Volume 32, March 1961, pp. 510-519.
[17]: “Shockley-Queisser Limit”, Article on http://www.wikipedia.org; Jun. 13, 2010.

### DETAILED DESCRIPTION OF THE DRAWINGS

FIG. 1: Illuminance as a function of a yellow LED's diode current at various temperatures. The slopes of the curves increase with decreasing temperature, showing at lower temperatures a greater rate of change in light output per mA of applied diode current.

FIG. 2: Increase in the rate of change in illuminance per mA of applied diode current as operating temperature decreases. The high temperature (≧−100° C.) slope of this curve is 29 lux per mA per ° C. decrease in temperature.

FIG. 3: Illuminance of a super-yellow LED as a function of temperature at various operating currents within the manufacturer's specifications, showing an almost 9 times improvement between 21° C. and −174° C.

FIG. 4: Another measurement by MTECH staff members, showing the decrease in forward diode current with decreasing temperature in a light emitting diode for a given light output.

FIG. 5: Shockley-Queisser efficiency calculations for solar cells of different bandgaps showing increased efficiencies with decreased temperatures.

FIG. 6: Schematic block diagram of aircraft lighting system. Shown are photovoltaic solar cells on aircraft wings, as well as LED arrangements on cooled fixtures inside an aircraft cabin.

Claimed is:

1. A lighting system comprising:
a. Photovoltaic devices;
b. A plurality of light sources such as solid-state LEDs;
c. LED fixtures;
d. Energy storage means;
e. Power conversion means;
f. Power distribution means; and
g. Thermal interfaces, heat pipes and thermal couplers used to cool said solid-state LEDs and LED fixtures.

2. The lighting system of claim (1) in which said photovoltaic devices are comprised of solar cells, positioned on the outside of an aircraft, that convert sunlight into energy, and in which said energy is transferred to at least one of said plurality of light sources, said energy storage means, said power conversion means, and said power distribution means.

3. The lighting system of claim (1) in which said plurality of light sources comprise of at least one of light emitting diodes and other light sources such as organic LEDs (OLEDs).

4. The lighting system of claim (1) in which said energy storage means comprises of at least one of capacitors, batteries, or other conventional and non-conventional energy storage means.

5. The lighting system of claim (1) in which said photovoltaic devices are mounted in such a way that they are able to capture external light and sunlight, for example light shining on either the wings or fuselage, or both, of an aircraft.

6. The lighting system of claim (1) in which the performance of said photovoltaic devices is enhanced through the reduced temperatures, such as those encountered in the atmosphere at high altitudes.

7. The lighting system of claim (1) in which said reduced temperatures are used to enhance the performance of said plurality of light sources via said thermal interface.

8. The lighting system of claim (1) in which at least one of the performance and the energy storage capabilities of said energy storage means is enhanced through reduced temperature operation.

9. The lighting system of claim (1) which is applied to aircraft, and in which said reduced temperatures are those encountered by an aircraft exterior during flight (e.g., at high altitudes or on ground during cold weather).

10. The lighting system of claim (1) in which said thermal interface extends through the body of said aircraft and transfers heat from the interior of said aircraft to the exterior of said aircraft for purposes of cooling electronic devices, including but not limited to said photovoltaic devices, said plurality of light sources, and said energy storage means.

11. The lighting system of claim (1) in which said power conversion means comprises of semiconductor-device-based inverters, converters, and other circuits, such as those incorporating MOSFETs, IGBTs, or other semiconductor devices whose performance is enhanced at reduced temperatures, and in which the performance of said power conversion means as a whole is enhanced through said reduced temperatures.

12. The lighting system of claim (1) using light transfer means such as fiber optic cables and light pipes from LEDs thermally connected to cool cabin walls to the cabin interior.

13. The lighting system of claim (1) wherein said solid-state LEDs are cooled by liquid nitrogen.

14. The lighting system of claim (1) wherein an air conditioning system is combined with the cooling system of the LEDs.

15. The lighting system of claim (1) wherein liquid nitrogen is generated by a cryo-cooler thermally connected to the cool outside atmosphere of the high-flying airplane.
